(19) United States
(12) Patent Application Publication
(10) Pub. No.: US 2026/0212087 A1
(43) Pub. Date: Jul. 23, 2026

(54) GENERATION AND/OR ADAPTATION OF 3D OBJECTS WITH RESPECT TO A FLOOR PLAN

(71) Applicant: SparX App Ltd., Tel Aviv-Yafo (IL)

(72) Inventors: Dan LOWENTHAL, Amikam (IL); Ehud LI-HOD, Ramat Gan (IL); Nativ LEVY, Hod Hasharon (IL)

(73) Assignee: SparX App Ltd., Tel Aviv-Yafo (IL)

(21) Appl. No.: 19/453,020

(22) Filed: Jan. 20, 2026

Related U.S. Application Data
(60) Provisional application No. 63/747,146, filed on Jan. 20, 2025.

(51) Int. Cl. G06F 30/27; G06F 30/13

(52) U.S. Cl. CPC G06F 30/27; G06F 30/13

(57) ABSTRACT

There is provided a method, comprising: feeding a combination of a 2D floor plan and a representation of objects into a generative artificial intelligence (GenAI) model, presenting within a GUI, the objects depicted as 3D object models complying with the target interior design plan outputted by the GenAI model and overlaid on the 2D floor plan, receiving via the GUI, an adaptation of a pose of a first set of 3D object models within the 2D floor plan, feeding into the GenAI model, a prompt comprising the adaptation of the pose, and dynamically updating the GUI for presenting an adaptation of a pose of a second set of 3D object models outputted by the GenAI model and complying with the target interior design plan, wherein 3D objects of the second set are excluded from the prompt fed into the GenAI model that includes the adaptation of the first set.

### RELATED APPLICATION

This application claims the benefit of priority under 35 USC § 119(e) of U.S. Provisional Patent Application No. 63/747,146 filed on Jan. 20, 2025. The contents of the above application are all incorporated by reference as if fully set forth herein in their entirety.

### FIELD AND BACKGROUND OF THE INVENTION

The present invention, in some embodiments thereof, relates to generative artificial intelligence (GenAI) models and, more specifically, but not exclusively, to a GenAI model for generating a digital floor plan.

Digital floor plans are computer-generated representations of an apartment or house's layout, created using design software like CAD or specialized floor plan tools. They may include dimensions, spatial arrangements, and structural details, offering a scalable and accurate blueprint. These plans are used for architectural design, real estate marketing, and space planning. They often integrate interactive elements, 3D modeling, and overlays for utilities or furniture placement. Digital formats enable easy sharing, editing, and visualization.

### SUMMARY OF THE INVENTION

According to a first aspect, a computer implemented method of generating a model of a premises with objects therein, comprises: accessing a 2D floor plan of the premises, accessing a representation of a plurality of objects complying with a target interior design plan, feeding a combination of the 2D floor plan and the representation of the plurality of objects into a generative artificial intelligence (GenAI) model, presenting within a graphical user interface (GUI), a plurality of the objects depicted as 3D object models complying with the target interior design plan outputted by the GenAI model and overlaid on the 2D floor plan, receiving via the GUI, an adaptation of a pose of a first set of 3D object models within the 2D floor plan, feeding into the GenAI model, a prompt comprising the adaptation of the pose, and dynamically updating the GUI for presenting an adaptation of a pose of a second set of 3D object models outputted by the GenAI model and complying with the target interior design plan, wherein 3D objects of the second set are excluded from the prompt fed into the GenAI model that includes the adaptation of the first set.

According to a second aspect, a system for generating a model of a premises with objects therein, comprises: at least one processor executing a code for: accessing a 2D floor plan of the premises, accessing a representation of a plurality of objects complying with a target interior design plan, feeding a combination of the 2D floor plan and the representation of the plurality of objects into a generative artificial intelligence (GenAI) model, presenting within a graphical user interface (GUI), a plurality of the objects depicted as 3D object models complying with the target interior design plan outputted by the GenAI model and overlaid on the 2D floor plan, receiving via the GUI, an adaptation of a pose of a first set of 3D object models within the 2D floor plan, feeding into the GenAI model, a prompt comprising the adaptation of the pose, and dynamically updating the GUI for presenting an adaptation of a pose of a second set of 3D object models outputted by the GenAI model and complying with the target interior design plan, wherein 3D objects of the second set are excluded from the prompt fed into the GenAI model that includes the adaptation of the first set.

According to a third aspect, a non-transitory medium storing program instructions for a model of a premises with objects therein, which when executed by at least one processor, cause the at least one processor to: access a 2D floor plan of the premises, access a representation of a plurality of objects complying with a target interior design plan, feed a combination of the 2D floor plan and the representation of the plurality of objects into a generative artificial intelligence (GenAI) model, present within a graphical user interface (GUI), a plurality of the objects depicted as 3D object models complying with the target interior design plan outputted by the GenAI model and overlaid on the 2D floor plan, receive via the GUI, an adaptation of a pose of a first set of 3D object models within the 2D floor plan, feed into the GenAI model, a prompt comprising the adaptation of the pose, and dynamically update the GUI for presenting an adaptation of a pose of a second set of 3D object models outputted by the GenAI model and complying with the target interior design plan, wherein 3D objects of the second set are excluded from the prompt fed into the GenAI model that includes the adaptation of the first set.

In a further implementation form of the first, second, and third aspects, further comprising: generating by the GenAI model, a virtual 3D model of the premises corresponding to the 2D floor plan, wherein the adaptation of the pose of the first set and of the second set comply with virtual structural limitations defined by the virtual 3D model of the premises.

In a further implementation form of the first, second, and third aspects, the virtual 3D model of the premises includes predicted locations of structural 3D features excluded from the 2D floor plan, wherein the adaptation of the pose of the first set and the second comply with virtual structural limitations of the structural 3D features.

In a further implementation form of the first, second, and third aspects, the GenAI model is trained on records, wherein a record includes a sample 2D floor plan and a corresponding sample 3D model of the sample 2D floor plan with sample structural 3D features.

In a further implementation form of the first, second, and third aspects, the structural 3D features excluded from the 2D floor plan include at least one of: windows, built-in furniture, partial-height walls, and doors or open doorways.

In a further implementation form of the first, second, and third aspects, the plurality of objects are selected from: furniture, fixtures, lighting, décor item, and accessories.

In a further implementation form of the first, second, and third aspects, further comprising automatically adapting at least one feature of the 3D object models and/or 2D floor plan in response to the prompt, the at least one feature complying with the target interior design plan, the at least one feature including: color scheme, material, and finishing.

In a further implementation form of the first, second, and third aspects, further comprising marking the 2D floor plan with placeholder and an indication of pose of each of the 3D object models corresponding to the pose of each of the 3D object models depicted in the GUI, for generating a marked 2D floor plan.

In a further implementation form of the first, second, and third aspects, marking further instructions for installation and/or assembly of real-life physical objects corresponding to the 3D object models.

In a further implementation form of the first, second, and third aspects, further comprising receiving via the GUI, a selection for fixing a pose of a third set of 3D object models, wherein the prompt fed into the GenAI model comprises the selection of the third set, and wherein the GenAI model generates the adaptation of the pose of the second set relative to the selection for fixing the pose of the third set and complying with the target interior design plan.

In a further implementation form of the first, second, and third aspects, further comprising feeding into the GenAI model in combination with the prompt, a set of rules defining relationships between the 3D object models and/or between the 3D object models and structural limitations of a virtual 3D model corresponding to the 2D floor plan wherein the adaptation of the pose of the second set complies with the set of rules.

In a further implementation form of the first, second, and third aspects, the GenAI model is trained on a training dataset of a plurality of records, each record including sample representations of a plurality of sample 3D object models positioned relative to a sample 2D floor plan, a sample prompt indicating an adaptation of pose of a first set of the sample 3D object models, and a ground truth indicating adaptation of the first set and of a second set of the sample 3D object models which were excluded from the sample prompt and are adapted in response to the prompt.

In a further implementation form of the first, second, and third aspects, the GUI is further configured for a user to place a virtual camera at a selected pose within the 2D floor plan overlaid with 3D object models, and further comprising generating an image depicting the 3D object models within a virtual 3D premises corresponding to the 2D floor plan as seen by the virtual camera from the selected pose.

In a further implementation form of the first, second, and third aspects, further comprising classifying rooms and/or regions of the 2D floor plan, wherein the 3D object models are positioned within the rooms and/or regions according to the classification and for complying with the target interior design plan.

In a further implementation form of the first, second, and third aspects, further comprising: obtaining from the GenAI model in response to the feeding, a proposed structural adaptation of the 2D floor plan for complying with the target interior design plan, wherein the proposed structural adaptation is dynamically adapted in response to the adaptation of the pose of the 3D object models.

In a further implementation form of the first, second, and third aspects, further comprising accessing at least one profile of one or more subjects expected to occupy the premises and/or of the premises, and automatically generating the target interior design plan according to the at least one profile.

In a further implementation form of the first, second, and third aspects, the at least one profile includes at least one of: expected use of the premises by the subjects, type of premises, geographical location of the premises, number of subjects, hobby of the subjects, seasonal trends, dimensions of the premises, personalized preference of the subjects, maximum estimated costs for implementing the target design plan, and preferred suppliers of features to be implemented according to the target interior design plan.

In a further implementation form of the first, second, and third aspects, the target interior design plan is automatically generated by feeding the at least one profile into a machine learning model trained on a dataset of records, wherein a record includes at least one sample profile and a ground truth of at least one sample interior design plan corresponding to the at least one sample profile.

In a further implementation form of the first, second, and third aspects, the target interior design plan is for a type of accessibility for a disabled individual, wherein the pose of the second set of 3D object models outputted by the GenAI model complies with the type of accessibility.

In a further implementation form of the first, second, and third aspects, further comprising simulating the disabled individual with the type of accessibility maneuvering within a 3D model of the premises corresponding to the 2D floor plan for identifying whether the pose of the second set of 3D object models complies with the type of accessibility when the simulation indicates successful maneuvering by the simulated disabled individual, or whether the pose of the second set of 3D object models does not comply with the type of accessibility with the simulation indicates failure to maneuver by the simulated disabled individual.

In a further implementation form of the first, second, and third aspects, further comprising in response to detecting the failure to maneuver by the simulated disabled individual, automatically instructing the GenAI model for re-generating the pose for obtaining success in the maneuver.

In a further implementation form of the first, second, and third aspects, the floor plan is generated from at least one image of an interior of a real-life premises captured by a camera.

In a further implementation form of the first, second, and third aspects, the at least one image comprises a video captured by a camera of a smartphone scanning the interior.

In a further implementation form of the first, second, and third aspects, further comprising: receiving via the GUI, another adaptation of a pose of a third set of 3D object models within the 2D floor plan, wherein 3D object models of the third set are selected from the first set and/or the second set, feeding into the GenAI model, a prompt comprising the adaptation of the pose of the third set, and dynamically updating the GUI for presenting an adaptation of a pose of a fourth set of 3D object models outputted by the GenAI model and complying with the target interior design plan, wherein 3D objects of the fourth set are excluded from the prompt fed into the GenAI model that includes the adaptation of the third set.

In a further implementation form of the first, second, and third aspects, further comprising iterating the receiving via the GUI, the feeding into the GenAI, and the dynamically updating the GUI, wherein in each iteration another set of 3D objects is adapted by a user via the GUI, wherein 3D objects of the another set are selected from 3D objects adapted by the user in a preceding iteration and 3D objects automatically adapted by the GenAI model in a preceding iteration.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a block diagram of components of a system for generating and/or adapting 3D object models for presentation over a floor plan, in accordance with some embodiments of the present invention;

FIG. 2 is a flowchart of a method for generating and/or adapting 3D object models for presentation over a floor plan, in accordance with some embodiments of the present invention;

FIG. 3A is a schematic of an exemplary GUI for generating and/or adapting 3D object models overlaid on a 2D floor plan, in accordance with some embodiments of the present invention;

FIG. 3B is a schematic of the exemplary GUI for generating and/or adapting 3D object models overlaid on a 2D floor plan from a top-down view, in accordance with some embodiments of the present invention;

FIG. 3C is a schematic of the exemplary GUI, depicting a perspective view of the 2D floor plan, in accordance with some embodiments of the present invention;

FIG. 3D is a schematic of the exemplary GUI depicting a top-down view of 3D object models of furniture overlaid on the 2D floor plan, in accordance with some embodiments of the present invention;

FIG. 3E is a schematic of the exemplary GUI depicting a perspective view of 3D object models of furniture overlaid on the 2D floor plan, in accordance with some embodiments of the present invention; and

FIG. 4 is a dataflow diagram depicting exemplary dataflow between a large language model and one or more other executing processes, in accordance with some embodiments of the present invention.

### DESCRIPTION OF SPECIFIC EMBODIMENTS OF THE INVENTION

The present invention, in some embodiments thereof, relates to machine learning models and, more specifically, but not exclusively, to a machine learning model for generating a digital floor plan.

As used herein, the term 3D object is sometimes used a shortened notation of the phrase 3D object model.

An aspect of some embodiments of the present invention relates to systems, methods, computing devices, and/or code instructions (stored on a data storage device and executable by one or more processors) for generating a model of a premises with 3D objects depicted therein. The object may include, for example, furniture, fixtures, lighting, décor item, and accessories. A floor plan of the premises is accessed. The floor plan may be a 2D floor plan and/or a 3D floor plan such as a 3D model of the premises. The floor plan may be generated from image of the premises captured by a camera (e.g., of a mobile phone), such as by scanning the interior of the premises using the camera. A representation of objects complying with a target interior design plan is accessed. For example, furniture of a certain designer, light fixtures of a certain theme, and the like. The floor plan and the representation of the objects are fed into a generative artificial intelligence (GenAI) model. 3D object models corresponding to the objects complying with the target interior design plan are outputted by the GenAI model. The 3D object models may be overlaid on the 2D floor plan. Alternatively, the 3D object models are presented within the 3D floor plan. The 3D object models may be generated by the GenAI model per room, for example, furniture suitable for a bedroom, furniture suitable for a kitchen, furniture suitable for a dining room, and furniture suitable for a living room.

Optionally, the 3D object models overlaid on the 2D floor plan (or positioned within the 3D floor plan) are presented within a graphical user interface (GUI). An adaptation of a pose of a first set of 3D object models within the 2D floor plan is received via the GUI. For example, a user moves the position of a table within a dining room, by displacing the table and rotating the table. A prompt comprising the adaptation of the pose is fed into the GenAI, for example, the prompt may be translated into instructions (e.g., move table 1 meter along the x-axis and rotate clockwise by 90 degrees), the prompt may be represented as a vector, the prompt may be a visual representation of the initial pose of the object and the adapted pose of the object, and the like. An adaptation of a pose of a second set of 3D object models is outputted by the GenAI model. The adaptation of the second set complies with the target interior design plan. For example, in response to the user moving and rotating the table, the GenAI automatically reposition chairs according to the new pose of the table. The GenAI may automatically adapt the pose of a bookcase and/or island according to the new pose of the table and chairs. The second set that is automatically adapted by the GenAI model is different than the first set adapted by a user, i.e., the second set is non-adapted by the user via the GUI. For example, the user does not move other furniture within the dining room via the GUI during movement of the table, such as the chairs, the bookcase, and the island are not moved. Placeholders and/or metadata indicating the specific 3D objects may be generated and associated with the 2D floor plan (and/or the 3D floor plan), for example, placeholders for the furniture may be marked on the 2D floor plan along with metadata indicating the model and/or color of each piece of furniture. This allows a real-life reconstruction of the virtual scene of the 3D object presented in the GUI.

At least one embodiment described herein addresses the technical problem of improving a user experience is selecting and/or positioning objects within a premises according to a target interior design plan. Different combinations of objects and/or features may be associated with each type of interior design plan, for example, different furniture items, décor, accessories, materials, finishes, and the like. It is difficult for a user, especially one who is not very experienced and/or knowledgeable in interior design, to select and/or position the correct objects in the correct location, in particular using the floor plan of the premises. It is difficult for such user to imagine what the final scene of the premises will look like. An error in selecting and/or positioning is difficult to correct, the objects may be expensive and/or difficult to move around. At least one embodiment described herein improves the technology of GUIs and/or GenAI models, by providing a GUI and/or GenAI model designed to improve a user experience in selecting and/or positioning objects within a premises according to a target interior design plan. At least one embodiment described herein improves over prior approaches of selecting and/or positioning objects within a premises according to a target interior design plan.

At least one embodiment described herein provides the practical application of dynamically updating a GUI for presenting 3D object models generated by a GenAI model overlaid on a 2D floor plan of a premises and/or positioned within a 3D model of the premises. The practical application may include automatic update of the GUI by automatic adaptation of a pose of one or more of the 3D objects in response to a user adapting one or more other objects.

At least one embodiment described herein improves over prior approaches, such as a standard 2D floor plan. Advantages over the 2D floor plan include: visualization, interface, and/or content. For example, standard 2D floor plan images do not depict space amenities and/or features well, for example, walls, doors, flooring, architectural style, windows, fixtures, and the like. It is difficult for a user to visualize the 3D space depicted by the standard 2D floor plan. Design elements may not match features of the premises (e.g., floor, fixtures) and/or the architectural style.

In another example, the prior approach is manual. For example, a 2D floor plan is obtained. The 2D floor plan may be cleaned and/or the background may be cropped, and/or other irrelevant parts may be removed. The 2D floor plan may be imported into a 3D editor tool. 3D objects, such as furniture, may be manually positioned on the floor plan. A 3D model may be exported, which may include baking, optimization, and/or compression. The 3D model may be displayed on a display, for example, within a CORT widget. Advantages over the manual approach include an automated generation of a 3D model based on the 2D model that complies with the target interior design.

In yet another example, the prior approach is based on photorealistic visualizations, such as renderings, videos, and virtual tools. Examples of improvements by at least one embodiment over photorealistic visualization include automatic adaptation of a pose of a set of 3D objects in response to a user adaptation of another set of 3D objects, recommendation for a structural adaptation to a 2D floor plan, quick setup, less friction, less expensive, better format for entire space overview at a glance, and others as described herein.

In at least one embodiment, the aforementioned technical problem is solved by, and/or the improvement to the aforementioned technical field is by, and/or the improvement over the aforementioned prior approaches is by, and/or the aforementioned practical application is achieved by: a GUI designed for a user to select an adaptation of a pose of a first set of 3D object models positioned overlaid on a 2D floor plan, for example, by dragging one of the 3D object models. A prompt indicating the adaptation of the pose is fed into a GenAI model. An adaptation of a pose of a second set of 3D object models is outputted by the GenAI model. The adaptation of the second set complies with the target interior design plan. Placeholders and/or metadata indicating the specific 3D objects may be generated and associated with the 2D floor plan (and/or the 3D floor plan), for example, placeholders for the furniture may be marked on the 2D floor plan along with metadata indicating the model and/or color of each piece of furniture. This allows a real-life reconstruction of the virtual scene of the 3D object presented in the GUI.

At least one embodiment described herein relates to an enhanced version of the traditional 2D floor plan, which may be used for a new digital standard for visualizing floor plans online. Embodiments described herein may be designed to coexist with other formats, for example, like standard 2D floor plans, renders, video walkthroughs, and virtual tours.

Some practical applications of the 3D model generated using at least one embodiment described herein are now described:
May be used by any entity using 2D digital floor plans to sell or rent spaces (e.g., any geography, any tier, and any stage), for example:
1. RE developers and owners (e.g., multi-family homes, condominiums, etc.)
2. Brokers and real estate agencies
3. Real estate marketplaces/platforms
May be used by interior designers or studios using floor plans to communicate designs to clients, such as during planning phase, for example:
   1. Interior design studios and individual designers
2. Interior design software platforms

Businesses selling content that may be laid and visualized through 3D models on top of floor plans as part of the interior design plan:
1. Furniture vendors
2. Decor item suppliers

### 3. Accessories (peloton, Yoga Mats Etc.).

Some potential advantages of at least one embodiment described herein are now described:
Engaging Interface
   Interactive, offering a “wow” effect and playability.
   A versatile, content-rich platform that delivers a personalized and dynamic experience, tailored to individual preferences, seasonal trends, hobbies, and more.
Increased Visualization Value
   Enables a better understanding of space from multiple angles.
   Photo-realistic 3D furniture models demonstrate space potential (functionality and practicality) with multiple design layouts.
Easy Frictionless Setup
   Based only on standard 2D floor plans. Applicable for built or planned/under construction projects.
   Quick, cost-effective remote design process using 3D models without site preparatory visits.
Revenue Opportunities
   New revenue stream for real estate-floor plan as a contextual ad space (rev share from content upsell).
   Virtual showrooms for vendors like furniture companies generating high-quality leads (person+space+timing+liked design).
   Potential to become a marketplace for RE, stagers, and interior designers, driving scale and revenues.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

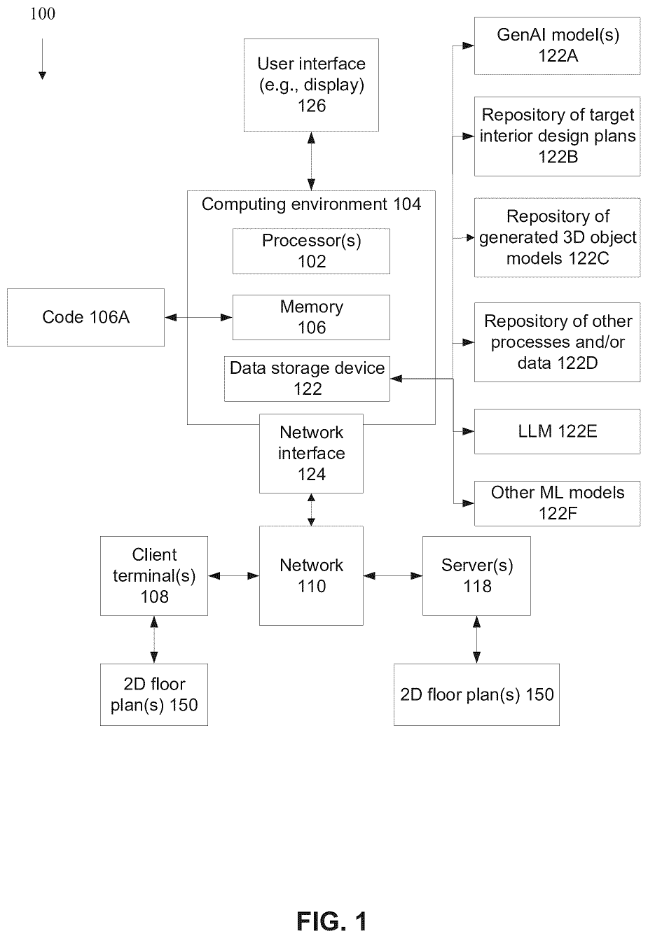

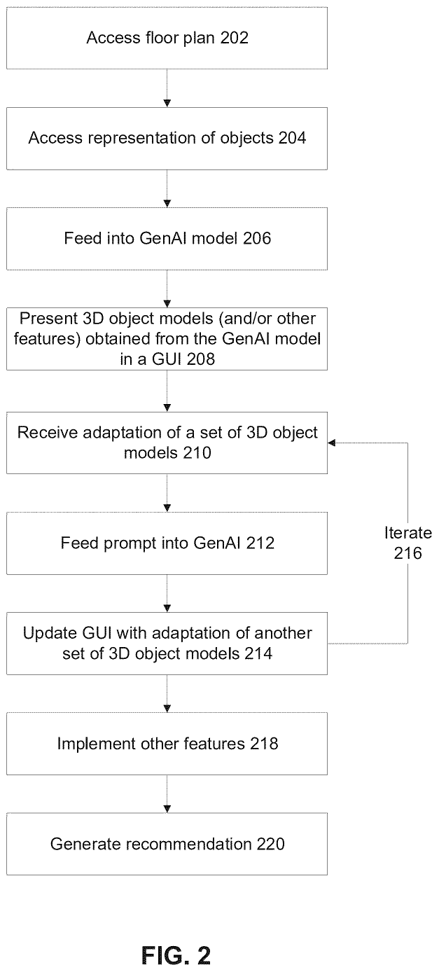

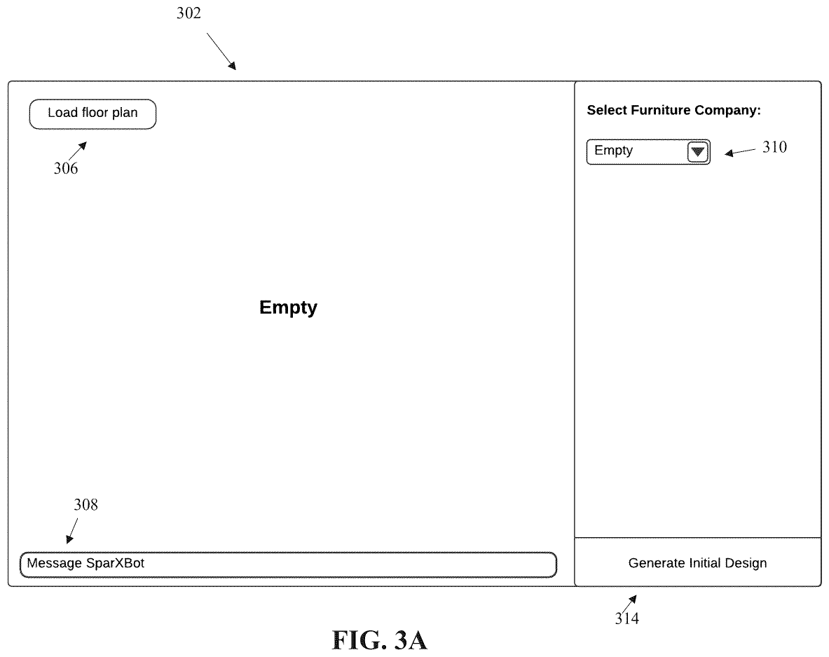

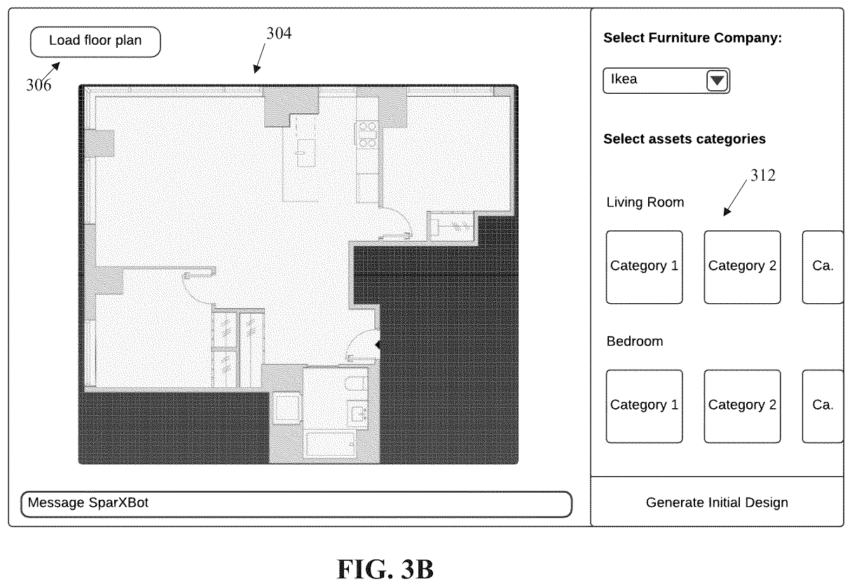

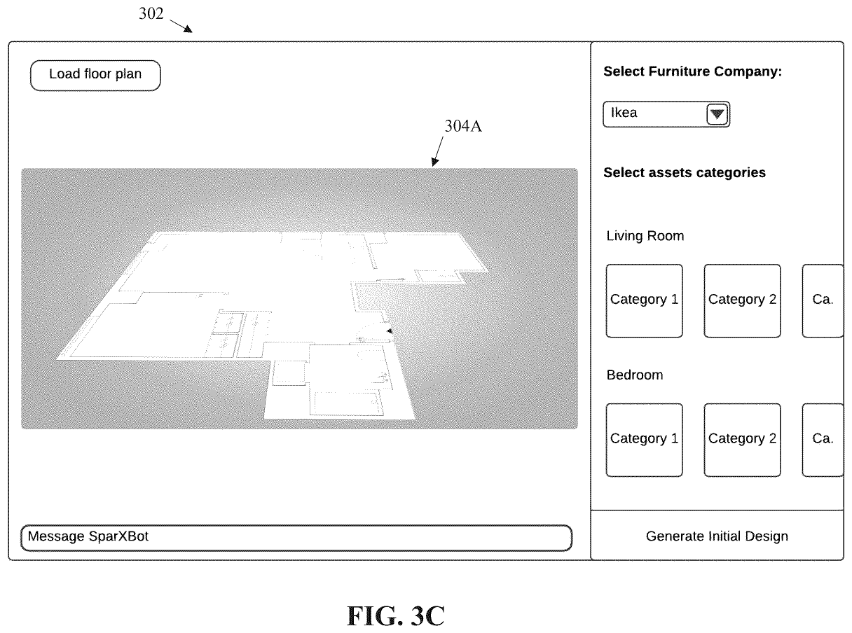

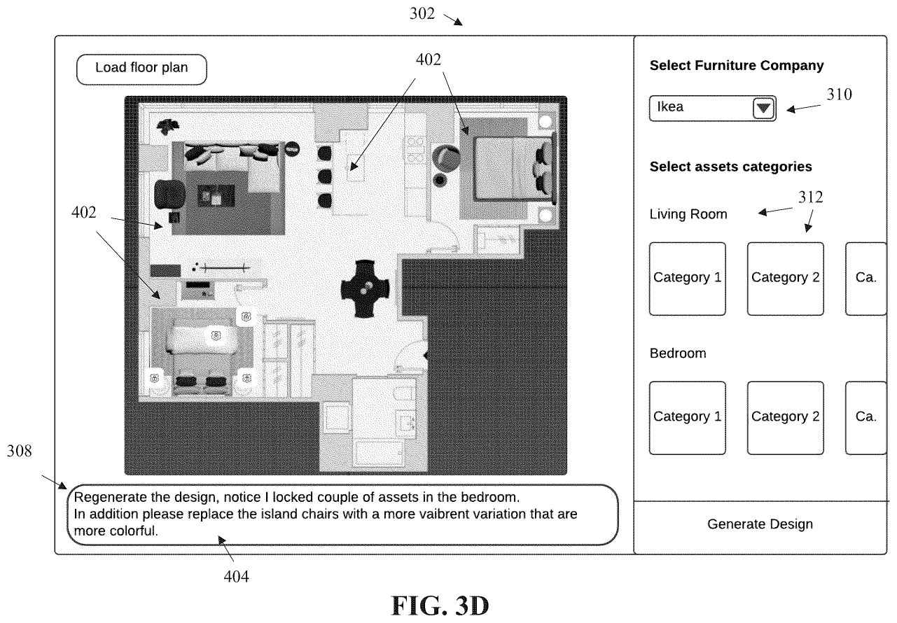

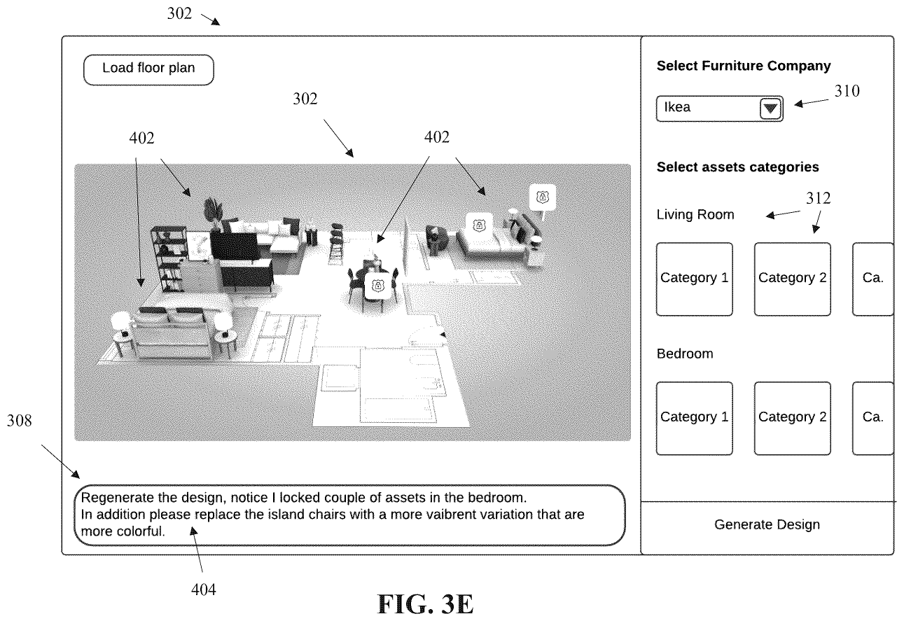

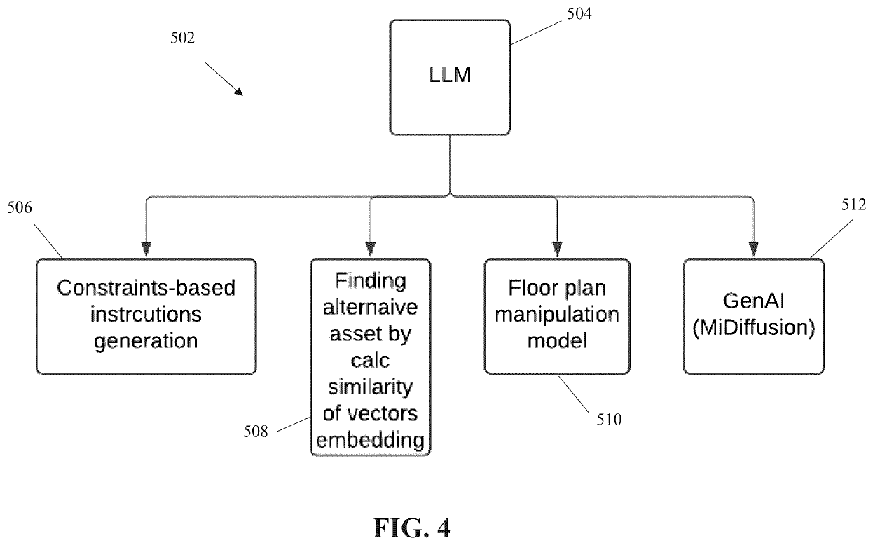

Reference is now made to FIG. 1, which is a block diagram of components of a system 100 for generating and/or adapting 3D object models for presentation over a floor plan, in accordance with some embodiments of the present invention. Reference is also made to FIG. 2, which is a flowchart of a method for generating and/or adapting 3D object models for presentation over a floor plan, in accordance with some embodiments of the present invention. Reference is also made to FIG. 3A, which is a schematic of an exemplary GUI 302 for generating and/or adapting 3D object models overlaid on a 2D floor plan, in accordance with some embodiments of the present invention. Reference is also made to FIG. 3B, which is a schematic of exemplary GUI 302 for generating and/or adapting 3D object models overlaid on a 2D floor plan 304 from a top-down view, in accordance with some embodiments of the present invention. Reference is also made to FIG. 3C, which is a schematic of exemplary GUI 302, depicting a perspective view 304A of the 2D floor plan, in accordance with some embodiments of the present invention. Reference is also made to FIG. 3D, which is a schematic of exemplary GUI 302 depicting a top-down view of 3D object models of furniture 402 overlaid on the 2D floor plan, in accordance with some embodiments of the present invention. Reference is also made to FIG. 3E, which is a schematic of exemplary GUI 302 depicting a perspective view of 3D object models of furniture 402 overlaid on the 2D floor plan, in accordance with some embodiments of the present invention. Reference is also made to FIG. 4, which is a dataflow diagram 502 depicting exemplary dataflow between a large language model 504 and one or more other executing processes 506, 508, 510, and 512, in accordance with some embodiments of the present invention.

System 100 may implement the acts of the method described with reference to FIGs. described herein, by processor(s) 102 of a computing environment 104 executing code instructions stored in a memory 106 (also referred to as a program store).

Computing environment 104 may generate 3D object models and/or adapt the pose of 3D object models and/or generate a 3D floor plan of a 2D floor plan, and/or other features described herein complying with a target interior design from an input of a 2D floor plan 150 of the premises and optionally a prompt indicating the target interior design, using one or more GenAI models 122A and/or one or more large language models (LLM) 122E and/or one or more other machine learning models 122F, as described herein.

GenAI model(s) 122A may include one or more GenAI models designed for generating the objects meeting the target interior design and/or for adapting a pose of one or of the objects for meeting the target interior design and/or other features described herein.

LLM 122E may be implemented as an orchestration layer that interprets user instructions (e.g., manually entered text prompt), determines the appropriate process to invoke, coordinates tasks between the system components, and/or other features described herein.

Machine learning models 122F and/or GenAI model(s) 122F may include a ML model designed for floor plan manipulation, for modifying the structural layout of the floor plan based on user instructions. The ML model may be trained on a set of geometrical floor plans.

Models described herein may be implemented using appropriate architectures, such as neural networks of various designs, trained using supervised and/or unsupervised approaches.

Computing environment 104 may be implemented as, for example one or more and/or combination of: a group of connected devices, a client terminal, a server, a web server, a virtual server, a computing cloud, a virtual machine, a desktop computer, a thin client, a network node, and/or a mobile device (e.g., a Smartphone, a Tablet computer, a laptop computer, a wearable computer, glasses computer, and a watch computer).

Multiple architectures of system 100 based on computing environment 104 may be implemented. For example:
*Computing environment 104 executing stored code instructions 106A, may be implemented as one or more servers (e.g., network server, web server, a computing cloud, and a virtual server) that provides centralized services (e.g., one or more of the acts described with reference to FIG. 2). Services may be provided, for example, to one or more client terminals 108 over network 110, and/or to one or more server(s) 118 over network 110. Client terminals 108, such as mobile devices, laptops, desktop computers, may provide 2D floor plan 150 to computing environment 104. 2D floor plan 150 may be locally stored by client terminal(s) 108 and/or may be remotely accessed by client terminal 108 (e.g., downloaded from a server, and/or a link to the 2D floor plan hosted by a server may be provided). Server(s) 118 may include, for example, web servers that host websites and/or social network from which 2D floor plans 150 may be accessed, and/or data storage servers that store data including 2D floor plans 150, which may be accessed and/or viewed and/or downloaded by client terminals 108. Services may be provided to client terminals 108 and/or server(s) 118, for example, as software as a service (SaaS), a software interface (e.g., application programming interface (API), software development kit (SDK)), an application for local download to the client terminal(s) 108 and/or server(s) 118, an add-on to a web browser running on client terminal(s) 108 and/or server(s) 118, and/or providing functions using a remote access session to the client terminals 108 and/or server(s) 118, such as through a web browser executed by client terminal 108 and/or server(s) 118 accessing a web sited hosted by computing environment 104. For example, 2D floor plan(s) 150 are provided from one or more client terminal 108 to computing environment 104. Computing environment 104 may centrally generate the 3D object models and/or adapt the pose of the 3D object models and/or generate the 3D floor plan, and/or other features described herein, complying with the target interior design plan, as described herein. The generated 3D object models and/or 3D floor plan may be, for example, provided to the corresponding client terminal 108, viewed on computing device 104 by the corresponding client terminal 108, and/or posted on server 118.
*Computing environment 104 may be implemented for local execution (i.e., include locally stored code instructions 106A) of one or more of the acts described with reference to FIG. 2, for locally generating 3D object models, and/or adapting 3D object models, and/or generating a 3D floor plan from 2D floor plan 150, and/or other features described herein, which comply with a target interior design plan. The locally stored code instructions 106A may be obtained from a server, for example, by downloading the code over the network, and/or loading the code from a portable storage device. 2D floor plan(s) 150 may be obtained, for example, locally generated by a user using a floor plan creation package, downloaded from a data storage device such as hosted by a server(s) 118, by a user manually entering a path where 2D floor plan(s) 150 is stored, and/or a user activating an application that automatically analyzes data on a network to find 2D floor plan(s) 150.

Processor(s) 102 of computing environment 104 may be hardware processors, which may be implemented, for example, as a central processing unit(s) (CPU), a graphics processing unit(s) (GPU), field programmable gate array(s) (FPGA), digital signal processor(s) (DSP), and application specific integrated circuit(s) (ASIC). Processor(s) 102 may include a single processor, or multiple processors (homogenous or heterogeneous) arranged for parallel processing, as clusters and/or as one or more multi core processing devices.

Memory 106 stores code instructions executable by hardware processor(s) 102, for example, a random access memory (RAM), read-only memory (ROM), and/or a storage device, for example, non-volatile memory, magnetic media, semiconductor memory devices, hard drive, removable storage, and optical media (e.g., DVD, CD-ROM). Memory 106 stores code 106A that implements one or more features and/or acts of the method described with reference to FIG. 2 when executed by hardware processor(s) 102.

Computing environment 104 may include a data storage device 122 for storing data, such as one or more code based processes described herein, for example, one or more GenAI models (s) 122A described herein, one or more repositories of interior design plans 122B, repository set to store the generated 3D object models 122C, and/or repository of other processes and/or data 122D (e.g., GUI for viewing the 3D object models overlaid on the 2D floor plan), and/or other code based data and/or processes, as described herein. Data storage device 114 may be implemented as, for example, a memory, a local hard-drive, virtual storage, a removable storage unit, an optical disk, a storage device, and/or as a remote server and/or computing cloud (e.g., accessed using a network connection).

Examples of other data that may be stored in 122D include: floor plans optionally represented as sets of vectors, a dataset of objects that may be positioned on the floor plan and/or automatically adapted as described herein, metadata, and vector embedding such as for style and/or appearance.

Network 110 may be implemented as, for example, the internet, a local area network, a virtual network, a wireless network, a cellular network, a local bus, a point to point link (e.g., wired), and/or combinations of the aforementioned.

Computing environment 104 may include a network interface 124 for connecting to network 110, for example, one or more of, a network interface card, a wireless interface to connect to a wireless network, a physical interface for connecting to a cable for network connectivity, a virtual interface implemented in software, network communication software providing higher layers of network connectivity, and/or other implementations.

Computing environment 104 and/or client terminal(s) 108 include and/or are in communication with one or more physical user interfaces 126 that include a mechanism for a user to enter data (e.g., generated a prompt by adapting a pose of one or more 3D object models) and/or view the displayed results (e.g., view the adapted pose of one or more other 3D object models generated by the GenAI model), optionally within a GUI. Exemplary user interfaces 126 include, for example, one or more of, a touchscreen, a display, gesture activation devices, a keyboard, a mouse, and voice activated software using speakers and microphone.

Referring now back to FIG. 2, at 202, a floor plan of a premises is provided and/or accessed.

The premises may be, for example, an apartment, a condominium, a house, a store, a hotel, an office, and the like.

The floor plan may be a 2D floor plan. Alternatively or additionally, the floor plan may be a 3D floor plan, such as a virtual 3D model of the premises. The 3D floor plan may correspond to a 2D floor plan. The 3D floor plan may be generated according to the 2D floor plan, for example, generated by a GenAI model fed the 2D floor plan, or constructed from the 2D floor plan using other imaging and/or CAD approaches.

Optionally, the GenAI model or another model generates a virtual 3D model of the premises based on the 2D floor plan. The 3D model generated by the GenAI model or another model may include predicted locations of structural 3D features excluded from the 2D floor plan, for example, windows, built-in furniture, partial-height walls, and doors or open doorways. The predicted structural 3D features may comply with the target interior design plan described herein. The target interior design plan may be fed into the GenAI in a prompt. The GenAI model may be trained on records, where a record may include a sample 2D floor plan and a corresponding sample 3D model of the sample 2D floor plan with sample structural 3D features.

The GenAI model used to create the virtual 3D model may be the same GenAI model used to generate the 3D object models. Alternatively, different GenAI models are used for creating the virtual 3D model and to generate the 3D object models.

At 204, a representation of objects may be provided and/or accessed. The objects may comply with a target interior design plan.

The target interior design plan and/or objects may be provided, for example, based on user input, from a predefined set (e.g., catalogue of a supplier), automatically selected by a process (e.g., machine learning, set of rules), and the like.

Optionally, the target interior design plan is automatically generated according to a profile, optionally implemented as metadata. The profile may be of one or more subjects expected to occupy the premises, for example, expected use of the premises by the subjects, number of subjects, hobby of the subjects, personalized preference of the subjects. Alternatively or additionally the profile may be the premises itself, for example, type of premises, geographical location of the premises, dimensions of the premises. The profile may include other metadata, for example, seasonal trends, maximum estimated costs for implementing the target design plan, and preferred suppliers of features to be implemented according to the target interior design plan.

The target interior design plan may be automatically generated by feeding the profile into a machine learning model. The machine learning model may be trained on a dataset of records, where a record includes a sample profile and a ground truth of a sample interior design plan.

Examples of objects include:
Furniture, for example, dining table, chair, sofa, coffee table, cabinet, shelving, and bed.
Fixtures, for example, coat hangers, sink, ceiling fan, and fire place.
Lighting, for example, chandelier, recessed lights, and wall lights.
Décor item, for example, painting, mirror, vase, and rug.
Accessories, for example, bath mat, candle arrangement, clock, and potted plants.
Air conditioning units.

The target interior design plan may define the objects and/or other features of the premises, such as materials and/or finishing.

The target interior design plan may be based one or more of:
Intended usage of the premises, for example, residential, commercial, open concept, and studio apartment.
Different themes and/or styles, for example, modern, minimalist, industrial, traditional, coastal, rustic, chalet style, eclectic, and the like.
Different functions of the premises, for example, for accessibility for wheelchairs and/or other disabilities, eco-friendly, and smart home design.

At 206, a combination of the floor plan and the representation of the objects is fed into a GenAI model.

Optionally, other data is fed into the GenAI in the combination of the floor plan and the representation of the objects, for example, the target interior design plan, and/or the profile and/or other metadata.

At 208, 3D object models complying with the target interior design plan are outputted by the GenAI model. The 3D object models are presented within a GUI.

The 3D object models may be presented as being positioned (e.g., overlaid) on the 2D floor plan. Alternatively or additionally, the 3D object models may be presented within the 3D floor plan.

The 3D object models may be arranged with respect to the 2D floor plan by the GenAI model for complying with the target interior design plan, for example, in a living room, a television is placed on a wall, a large sofa is placed facing the television, a coffee table is placed between the television and the large sofa, a light is fixed to the ceiling above the coffee table, and other objects are positioned accordingly.

Optionally, rooms and/or regions of the 2D floor plan are classified. The 3D object models may be positioned within the rooms and/or regions according to the classification and for complying with the target interior design plan. The classification may be implicitly performed by the GenAI model, and/or may be performed by another process such as by a trained classifier, a set of rules, and the like. For example, the GenAI model places beds and dressers in bedrooms, places a dining table and chairs in a dining room, and places a television and sofa in a den.

At 210, an adaptation of a pose of a set of 3D object models within the 2D floor plan is received via the GUI.

The adaptation of the pose may include a displacement and/or change in orientation of the 3D objects, along one or more axes and/or along one or more degrees of freedom.

Optionally the displacement is along a 2D plane defined by the 2D floor plan, when the 3D object is placed on the floor. For objects placed along the wall or ceiling, the displacement may be along the 2D plane defining the wall, and/or may be between walls, such as movement to an opposite wall, or a different wall in the room.

Optionally, the adaptation of the pose (e.g., displacement) is limited by virtual barriers defined by the 2D floor plan and/or by the 3D model based on the floor plan. For example, a table cannot be placed half in one room and half in a second room across a wall. In another example, a table should not be placed in front of an open door. Alternatively, the adaptation of the pose is not limited. The user may make any adaptation they wish, even across virtual barriers such as walls and/or violating rules such as placing objects in doorways. In such embodiments, the GenAI model may adapt the floor plan to fit the adaptation, for example, moving a wall, moving a doorway, making an opening in a wall, and the like.

The adaptation of the pose may be performed, for example, by a user dragging and dropping the 3D object, and/or rotating the 3D object using an interface such as a mouse, verbal command, and the like.

Alternatively or additionally, the adaptation is of one or more features of the 3D object model complying with the target interior design plan, for example, the user may wish to change a color scheme, material, and/or finishing. Such adaptation may be done via the GUI, for example, by right clicking the 3D object, which pulls up a list of colors, materials and/or finish to select from, which comply with the target interior design plan.

Optionally, a selection for fixing a pose of yet another set of 3D object models may be received via the GUI. For example, via a click on a certain 3D object, drawing a bounding box around the certain 3D object, a verbal description of the 3D object, and the like. For example, the moves a sofa in a living room, and selects the television to be fixed in the current pose.

At 212, a prompt indicating the adaptation of the pose (and/or feature) is obtained and/or generated, and fed into the GenAI model.

The prompt may be automatically generated based on the user's interaction with the GUI, such as based on the user's selection of object(s) and/or adaptation of object(s) via the GUI. For example, the prompt may include the selection of 3D objects which are to remain fixed at the

current poses, i.e., not to be adapted by the GenAI model. Alternatively or additionally, the prompt may be manually entered as text by a user, optionally via the GUI.

The prompt may be implemented, as for example:
A text description, for example, move table from the middle of the room to the back of the room, move table from coordinates x1,y1 to x2,y2, turn bed 90 degrees, change to color code THX101, change to finish code 8723, and the like.
A vector indicating the change in pose.
A data structure representing the visual change in pose depicted in the GUI.

The prompt may be automatically generated in response to adaptation of object(s) depicted in the GUI using the following exemplary approach. The origin transform of the object(s) and the new position transform of the object(s) are used to describe the GenAI model's generation. The origin transform represents the GenAI model's initial position at the beginning of the GUI session, while the new transform represents its position after one or more movements, essentially capturing

the state at the point when the user attempts to regenerate the design. Each transform includes translation and/or rotation components, and scaling is optional. To provide clear communication with the GenAI, a textual description may be generated in addition to or alternatively to the numerical values. For example: for rotation, the following prompt may be automatically generated based on the user manipulation of objects via the GUI: “The sofa model has been rotated 90 degrees to the left. Its new orientation relative to the world coordinate system is represented by the Euler angle (0, π/2, 0).” For translation, the following prompt may be automatically generated based on the user manipulation of objects via the GUI: “The sofa model has been moved. Its new position is 5 meters along the X-axis and 1 meter along the Y-axis relative to the world coordinate system and can be represented using vector (5,1,0).”

Optionally, the prompt references the 3D object models generated by the GenAI model. The same GenAI model that generated the 3D object models may be used to adapt the 3D object models based on the prompt. Optionally, a set of rules is fed into the GenAI model in combination with the prompt. The set of rules may define relationships between the 3D object models and/or between the 3D object models and structural limitations of the floor plan, for example, structural limitation of a virtual 3D model corresponding to the 2D floor plan.

Examples of rules that may be included in the set include:
Do not place 3D object models in a doorway.
Do not place 3D object models within 1 meter of an air conditioner.
Do not block a window with a 3D object model.
In a living room, organize furniture around the television.
Leave enough room for a person to be able to get in and out of their bed.

The GenAI model may be trained on a training dataset of records. Each record may including a sample representations of sample 3D object models positioned relative to a sample 2D floor plan, a sample prompt indicating an adaptation of pose (and/or feature) of a set of the sample 3D object models, and a ground truth indicating adaptation of pose (and/or feature) of the set of sample 3D object models included in the sample prompt and another set of sample 3D object models not included in the sample prompt which are adapted in response to the adaptation included in the prompt.

Optionally, a LLM is designed for providing central decision making, and/or directing tasks between one or more GenAI models, machine learning models, and/or datasets described herein.

Optionally, a communication protocol is defined for interaction between the LLM and GenAI model. The communication protocol may be defined for ensuring seamless interaction between the LLM and/or GenAI model and/or for enabling efficient task execution.

User instructions (e.g., manually entered text and/or selections via the GUI such as by clicking and/or dragging) may be translated into structured commands by the LLM, for example, JSON-like structured commands. These commands may specify, for example, the function and/or process to invoke, inputs required, and/or any constraints. An example of a JSON-like structured command is as follows:
{“method”: “SceneCompletion”, “inputs”: {“floorplan”: “path/to/floorplan”, “lockedAssets”: [{“id”: “sofa_1”, “position”: [3.5, 2.0], “rotation”: 90}, {“id”: “table_1”, “position”: [4.0, 3.0], “rotation”: 0}]}}

The LLM may provide the structured command to the GenAI, for example, via an API and/or direct function call. The GenAI processes the command and returns the result, which may include, for example: updated 3D models transforms, status messages (e.g., success, failure, or warnings), and/or other outcomes described herein.

At 214, the GUI is dynamically updated based on the output of the GenAI model in response to the prompt, for presenting an adaptation of a pose (and/or feature) of another set of 3D object

models excluded (i.e., not included) in the prompt fed into the GenAI model. The other set is automatically adapted in response to the prompt, even though the user did not explicitly adapt the other set. The other set is different than the set included in the prompt fed into the GenAI model, and is non-adapted by a user via the GUI. For example, the user moves a table from one end of a dining room to another end of the dining room, and rotates the table 90 degrees, and may change the color of the table. The GenAI automatically repositions the chairs around the dining room at its new location and orientation, and may automatically change the color of the chairs to correspond to the color of the table. This spares the user from having to move and reposition each chair accordingly, and from changing the color of each chair.

When the prompt fed into the GenAI model includes the set of 3D objects selected to remain fixed at the current pose, the GenAI model generates the adaptation of the other set relative to the adapted set and relative to the fixed set of 3D objects, where the adaptation is generated to comply with the target interior design plan.

The pose of the other set of 3D object models outputted by the GenAI model may be generated to comply with the target interior design plan.

The adaptation of the pose of the other set outputted by the GenAI model may be generated to comply with the set of rules fed into the GenAI in combination with the prompt.

The adaptation of the pose of the set adapted by the user and of the other set adapted by the GenAI model may be generated to comply with virtual structural limitations defined by the virtual 3D model of the premises.

At 216, one or more features described with reference to 210-214 may be iterated. In each iteration, another set of 3D object models may be adapted by the user via the GUI, and the GenAI model may adapt the other set of 3D objects according to the set adapted by the user included in the prompt fed into the GenAI. The 3D objects may be iteratively adapted, for example, in a first iteration, the user uses the GUI to adapt a first set of 3D object models, and the GenAI model adapts a second set of 3D object models according to the adaptation of the first set, which is presented in the GUI. In a second iteration, the user adapt a third set of 3D object models from the second set of 3D object models that were adapted by the GenAI model in the preceding iteration. The GenAI model adapts a fourth set of 3D object models according to the adaptation of the third set. For example, in a living room that includes a television, a coffee table, and a sofa, the user moves the sofa to another location. In response, the GenAI model automatically reposition the television and the coffee table relative to the new location of the sofa. In a next iteration, the user rotates the television by 90 degrees. In response, the GenAI model automatically repositions and re-orients

the coffee table and sofa to face the television at its new orientation. In yet another iteration, the user changes the finishing of the surface of the coffee table. In response, the GenAI model adds a picture on the wall that corresponds to the adapted finishing of the surface.

At 218, one or more additional features may be implemented.

The additional features may be implemented, for example, using the GUI, by the GenAI model as part of the iterations described with reference to 212-216, prior to the iterations, after the iterations, and/or independently of the iterations.

Optionally, the (2D or 3D) floor plan is marked with placeholder and optionally an indication of pose (i.e., location and/or orientation) of each of the 3D object models. The pose indicated on the floor plan may correspond to the pose depicted in the GUI. For example, the user uses the GUI to iteratively change pose of furniture, until they obtain an arrangement of furniture the user likes. The user may click an icon to automatically mark the floor plan with the pose of the furniture depicted in the GUI.

The marking of the 3D objects may include instructions for installation and/or assembly of real-life physical objects corresponding to the 3D object models. The instructions may be in human readable form to enable the user to re-create the virtual arrangement depicted in the GUI in real life. For example, position television 2 meters from the right wall, position the sofa such that the television is in the middle of the sofa, place sofa 3 meters in front of the television, place coffee table closer to the sofa than to the television, etc. . . .

Alternatively or additionally, the GUI is designed to enable a user to virtually place a virtual camera at a selected pose within the (2D) floor plan overlaid with 3D object models depicted in the GUI. For example, the GUI depicts a virtual kitchen with island, stools, shelves, kitchen cabinets, etc. . . . An image depicting the 3D object models within a virtual 3D premises corresponding to the 2D floor plan as seen by the virtual camera from the selected pose may be automatically generated. The image may be dynamically generated in response to real-time change of the pose of the virtual camera by the user. For example, the user may place the virtual camera on one of the stools, facing the island positioned in front of shelves. An image of what the virtual camera “sees” is presented.

The user then turns the camera 45 degrees. The image is automatically updated according to the new orientation of the camera. The user then moves the camera to another location in the kitchen. The image is updated according to the new location of the camera.

Alternatively or additionally, the GenAI model generates a proposed structural adaptation of the 2D and/or 3D floor plan for complying with the target interior design plan. The structural adaptation may be generated in response to a prompt, for example, a combination of the 2D floor plan and the target interior design plan. The GenAI model may be the same GenAI model that generates the 3D object models and/or the adaptation of the set of 3D object models, or another GenAI model such as dedicated to generate the proposed structural adaptation of the floor plan. When the GenAI model is fed a change of pose of a set of 3D object models, as described herein, the proposed structural adaptation generated by the GenAI model may be dynamically adapted in response to the adaptation of the pose of the 3D object models. For example, when the user moves a bookcase in front of a window (blocking the window), the GenAI model may change the location of the window on the floor plan.

The structural adaptation may be presented within the GUI, such as to enable a user to change views within an interior of the 3D model based on the 2D floor plan.

The structural adaptation of the 2D floor plan may be automatically generated by the GenAI model for structurally complying with at least one 3D object model inserted into the 3D model of the premises, where the 3D object model complies with the target interior design plan.

The structural adaptation may be automatically generated for at least one of the following for complying with the target interior design plan: fitting built-in furniture against an interior wall, accommodating built-in furniture of a kitchen, enabling placement of a picture and/or mirror on an interior wall, accommodating built-in furniture of a bathroom, accommodating furniture of a bedroom and/or living room, accommodating an open-concept kitchen design, increasing privacy, increasing open space, creating a log-cabin atmosphere, creating a profession office atmosphere.

Examples of structural adaptation include at least one of: adding an interior wall, removing an interior wall, removing a part of a wall, adding a window from an interior wall, removing a window from an interior wall, adding a door, removing a door, changing location of a door, enlarging a room, combining two rooms into a single larger room, converting a patio and/or balcony into a room, converting a room into a patio and/or balcony, adding a pergola to a patio and/or balcony.

The structural adaptation of the 2D floor plan may be visually indicated within the 3D model. The GUI may include a toggle for toggling between the 3D model with the structural adaptation of the 2D floor plan and complying with the target interior design plan, and an adapted 3D model according to the 2D floor plan excluding the structural adaptation. Optionally, the model designed for floor plan manipulation (e.g., Floor Plan Manipulation Model) is designed to handle vector-based structural modifications of the floor plan. The floor plan manipulation model interprets instructions to add, remove, and/or reposition structural elements (e.g., adapt pose), for example, walls, windows, and/or doors.

Exemplary functional that may be executed by the floor plan manipulation model include:
AddElement:
   Purpose: Adds new structural elements to the floor plan (e.g., walls, doors, and windows).
   Inputs:
      Element type (e.g., wall, window).
      Start and end coordinates for the vector.
   Outputs:
      Updated floor plan with the new element.
RemoveElement:
   Purpose: Removes existing structural elements from the floor plan.
   Inputs:
      Identification of the element to remove (e.g., vector ID or coordinates).
   Outputs:
      Updated floor plan without the specified element.
ModifyElement:
   Purpose: Modifies properties of an existing structural element (e.g., repositioning a wall or resizing a window).
   Inputs:
      Element identification and new properties (e.g., updated coordinates or dimensions).
   Outputs:
      Updated floor plan with the modified element.
OptimizeLayout:
   Purpose: Adjusts the entire floor plan to improve layout efficiency (e.g., optimize room dimensions or structural alignment).
   Inputs:
      Optimization constraints (e.g., room proportions, accessibility requirements).
   Outputs:
      Optimized Floor Plan.

A communication protocol may be defined for communication between the LLM and the floor plan manipulation model. For example:
Instruction Parsing:
   The LLM analyzes user instructions to identify structural modification tasks.
   Example user instructions:
      “Add a door to the living room wall.”
      “Remove the partition between the kitchen and dining area.”
      “Resize the bedroom to make it 4×5 meters.”
Instruction Translation:
   Translates parsed instructions into structured commands for the Floor Plan Manipulation Model.
   A pseudocode code of an example command for adding a door is now provided:
{“method”: “AddElement”, “inputs”: {“type”: “door”, “coordinates”: {“start”: [3.0, 2.0], “end”: [3.5, 2.0]}}}
Execution:
   Sends commands to the Floor Plan Manipulation Model via an API or direct function call.
   Receives updated floor plan data in return.
Result Integration:
   Updates the floor plan in the backend.
   Refreshes the GUI to reflect the structural modifications.

Alternatively or additionally, the target interior design plan defines a type of accessibility for a disabled individual to be met by the premises, for example, for physical accessibility, such as being wheel chair accessible, accessible for use of crutches, and accessible for use of a walker or cane. Other examples of accessibility include: for cognitive impaired accessibility, visually impaired accessibility, and elderly accessibility (e.g., to help prevent falls, and/or reduce exertion). The target interior design plan for accessibility may be met, for example, by wider doorways and/or hallways ramps, defining a height for furniture (e.g., shelves, table, counter) according to the expected reach of the individual (e.g., sitting in a wheelchair), and the like. The GenAI model generates 3D object models and/or adapts the pose of the set of 3D object models and/or the 3D model based on the 2D floor plan (and/or other generation described herein) to comply with the type of accessibility.

Optionally, a simulation is performed based on the 3D object models and/or the 3D model based on the 2D floor plan generated by the GenAI model complying with the type of accessibility. A disabled individual with the type of accessibility defined by the target interior design plan may be simulated. For example, the disabled individual is simulated as maneuvering within the 3D model of the premises corresponding to the 2D floor plan for identifying whether the generated 3D object models and/or the adapted pose of the 3D object models complies with the type of accessibility. The simulation may include for example, a person in a wheel chair maneuvering between the 3D object models, with the person in the wheelchair getting in and out of their bed and/or using counters and/or tables. The simulation may be presented in the GUI, to enable the user to view the simulation in order to help the user understand the success or failure of the generation by the GenAI model. The simulation may indicate that the generated 3D model of the 2D floor plan and/or 3D object models and/or adaptation of the 3D object models meet the target interior design plan by successful maneuvering by the simulated disabled individual. Alternatively, the simulation may indicate that the target interior design plan is not met (e.g., the adapted pose of the set of 3D object models does not comply with the type of accessibility) when the simulated disabled individual fails to be able to maneuver, such as cannot access certain areas, cannot get in or out of their bed, cannot reach the counter, and the like. Optionally, in response to detecting the failure to maneuver by the simulated disabled individual, the GenAI model may be automatically instructed for re-generating the 3D objects and/or adaptation of the pose of the 3D objects, and/or the 3D model of the floor plan, for obtaining success in the maneuver based on the determined failure in the simulation. For example, the GenAI model may be instructed to lower the height of the table and/or counter, increase size of the doorways/halls, increase distance between furniture, and the like.

Alternatively or additionally, the GUI includes an option for selecting a specific 3D object model and for ordering the specific 3D object model for installation and/or placement within a real physical premises corresponding to the installation and/or placement of the 3D object model in the GUI.

At 220, a recommendation is generated accordingly.

The recommendation may include the 3D model of the premises based on the 2D floor plan, the generated 3D object models, the adaptation of pose of the 3D object models, and/or other features generated by the GenAI model described herein.

The recommendation may be implemented as, for example, the 2D floor plan with placeholders indicating locations for placing of the real life objects corresponding to the 3D object models optionally with metadata indicating the type of the 3D object models and/or instructions for obtaining/installing/assembling the 3D object models, an image or video presenting the 3D object models overlaid on the 2D floor plan, and/or an interactive dataset of the 3D object models

overlaid on the 2D floor plan (e.g., as presented in the GUI), a text description of what the 3D object models are and/or where to place the 3D object models, a file for 3D printing of a small model depicting the 3D object models over the 2D floor plan, and the like.

Optionally, the 2D floor plan which was used may automatically overlaid with the generated 3D object models. For example, a 2D floor plan hosted by a server may be automatically identified. The 2D floor plan hosted by the server may be automatically overlaid with the generated 3D object models. Client terminals accessing the 2D floor plan on the server may view the 2D floor plan overlaid with the generated 3D object models, rather than the 2D floor plan alone.

An exemplary workflow based on at least one embodiment described herein, implemented using components of the system described with reference to FIG. 1 and/or the method described with reference to FIG. 2 is now described:
1. Full Interior Design Generation
User Instruction: “Generate a modern interior design for this 2D floor plan.”
Process:
   LLM determines that the GenerateEntireFloorplan method in the GenAI model should be invoked.
   The 2D floor plan and design constraints are prepared and sent to the GenAI model.
   The GenAI model generates a complete 3D design, which is returned to the backend and rendered in the GUI.
2. Scene Completion
User Instruction: “Keep the sofa and dining table where they are, and redesign the rest of the living room.”
Process:
   LLM interprets the instruction and invokes the SceneCompletion method in the GenAI model.
   Locked asset positions and design constraints are sent to the GenAI model.
   The GenAI model generates a partial design, which is integrated into the GUI.
3. Structural Modification
User Instruction: “Add a window to the north wall.”
Process:
   LLM identifies this as a structural modification task and invokes the Floor Plan Manipulation Model.
   The Floor Plan Manipulation Model adds a vector representing the window to the floor plan and returns the updated layout.
   The GUI refreshes to display the new window.
4. Style Adaptation
User Instruction: “Change this chair to a Scandinavian style.”
Process:
   LLM retrieves the chair's vector embedding and finds a similar asset with the desired style.
   The backend updates the asset data, and the new 3D model is rendered in the GUI.
5. Position Transformation
User Instruction: “Move the sofa 2 meters to the right and rotate it 90 degrees.”
Process:
   LLM generates a transformation script for the web editor (e.g., using the 3.js library).
   The script is executed, updating the sofa's position and orientation in the GUI.
6. Layout Optimization
User Instruction: “Optimize the kitchen layout for better space efficiency.”
Process:
   LLM interprets the instruction and invokes the OptimizeLayout method in the Floor Plan Manipulation Model.
   The model adjusts the kitchen's dimensions and layout, returning the optimized floor plan.
   The GUI reflects the changes dynamically.

Referring now back to FIG. 3A, exemplary GUI 302 for generating and/or adapting 3D object models overlaid on the 2D floor plan, is presented at an initial state, where a 2D floor plan has not yet been loaded and/or is not yet presented. The 2D floor plan may be loaded, for example, using an icon 306. A window 308 designed for a user to enter text instructions may be presented in GUI 302. Window 308 may be used, for example, to enter prompts for adaptation of one or more 3D objects, which are fed into the GenAI, as described herein. GUI 302 may include other exemplary features used to control generation and/or pose of the 3D object models for meeting the target interior design plan. For example, a drop down menu 310 may be used for selecting a specific provider (e.g., furniture company), which enables a selection from 3D models of furniture available by the selected provider which for positioning over the 2D floor plan and/or for adaptation thereof. An initial design of 3D object models overlaid on the 2D floor plan may be generated by clicking icon 314.

Referring now back to FIG. 3B, a 2D floor plan 304 is presented within GUI 302. 2D floor plan 304 has been loaded, for example, using icon 306. The user may select to generate 3D objects for specific rooms and/or to view specific rooms with 3D objects overlaid on 2D floor plan 304 of the specific room, for example, by clicking a respective icon 312.

Referring now back to FIG. 3C, exemplary GUI 302 depicts a perspective view 304A of 2D floor plan 304.

Referring now back to FIG. 3D, exemplary GUI depicts a top-down view of 3D object models of furniture 402 overlaid on 2D floor plan 304. 3D object models of furniture 402 are created by the GenAI model for complying with the target interior design plan, and according to the selection made via drop down menu 310 and/or selection icons 312. An instruction prompt 404 manually entered as text by a user via window 308 is presented. Instruction prompt 404 is fed into the GenAI model for dynamically adapting 3D object models of furniture 402, as described herein.

Referring now back to FIG. 3E, exemplary GUI 302 depicting a perspective view of 3D object models of furniture 402 overlaid on the 2D floor plan, is presented.

Referring now back to FIG. 4, dataflow diagram 502 depicts the exemplary dataflow between large language model 504 and one or more other executing processes, for example, constraints-based instructions generation 506, finding at least one alternative object model (e.g., asset) by calculating similarity of vector embedding 508, a floor plan manipulation model 510, and a GenAI model 512, as described herein. Process 506 may apply constrains to generation and/or adaptation of 3D objects and/or 3D floor plans described herein, for example, by predefined rules, manually entered user instructions, a predefined profile, and the like. Process 508 may adapt the 3D object models to other similar 3D object models, for example, switch the type of sofa such as from a 3 seater to a 2 seater, change a floor lamp to a ceiling light, switch a 3 seater sofa from one provider to a 3 seat from another provider and the like.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It is expected that during the life of a patent maturing from this application many relevant GenAI models will be developed and the scope of the term GenAI model is intended to include all such new technologies a priori.

As used herein the term “about” refers to ±10 %.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A computer implemented method of generating a model of a premises with objects therein, comprising:
accessing a 2D floor plan of the premises;
accessing a representation of a plurality of objects complying with a target interior design plan;
feeding a combination of the 2D floor plan and the representation of the plurality of objects into a generative artificial intelligence (GenAI) model;
presenting within a graphical user interface (GUI), a plurality of the objects depicted as 3D object models complying with the target interior design plan outputted by the GenAI model and overlaid on the 2D floor plan;
receiving via the GUI, an adaptation of a pose of a first set of 3D object models within the 2D floor plan;
feeding into the GenAI model, a prompt comprising the adaptation of the pose; and
dynamically updating the GUI for presenting an adaptation of a pose of a second set of 3D object models outputted by the GenAI model and complying with the target interior design plan,
wherein 3D objects of the second set are excluded from the prompt fed into the GenAI model that includes the adaptation of the first set.

2. The computer implemented method of claim 1, further comprising:
generating by the GenAI model, a virtual 3D model of the premises corresponding to the 2D floor plan,
wherein the adaptation of the pose of the first set and of the second set comply with virtual structural limitations defined by the virtual 3D model of the premises;
wherein the plurality of objects are selected from: furniture, fixtures, lighting, décor item, and accessories.

3. The computer implemented method of claim 2, wherein the virtual 3D model of the premises includes predicted locations of structural 3D features excluded from the 2D floor plan, wherein the adaptation of the pose of the first set and the second comply with virtual structural limitations of the structural 3D features.

4. The computer implemented method of claim 3, wherein the GenAI model is trained on records, wherein a record includes a sample 2D floor plan and a corresponding sample 3D model of the sample 2D floor plan with sample structural 3D features, wherein the structural 3D features excluded from the 2D floor plan include at least one of: windows, built-in furniture, partial-height walls, and doors or open doorways.

5. The computer implemented method of claim 1, further comprising automatically adapting at least one feature of the 3D object models and/or 2D floor plan in response to the prompt, the at least one feature complying with the target interior design plan, the at least one feature including: color scheme, material, and finishing.

6. The computer implemented method of claim 1, further comprising marking the 2D floor plan with placeholder and an indication of pose of each of the 3D object models corresponding to the pose of each of the 3D object models depicted in the GUI, for generating a marked 2D floor plan, wherein marking further instructions for installation and/or assembly of real-life physical objects corresponding to the 3D object models.

7. The computer implemented method of claim 1, further comprising receiving via the GUI, a selection for fixing a pose of a third set of 3D object models, wherein the prompt fed into the GenAI model comprises the selection of the third set, and wherein the GenAI model generates the adaptation of the pose of the second set relative to the selection for fixing the pose of the third set and complying with the target interior design plan.

8. The computer implemented method of claim 1, further comprising feeding into the GenAI model in combination with the prompt, a set of rules defining relationships between the 3D object models and/or between the 3D object models and structural limitations of a virtual 3D model corresponding to the 2D floor plan wherein the adaptation of the pose of the second set complies with the set of rules.

9. The computer implemented method of claim 1, wherein the GenAI model is trained on a training dataset of a plurality of records, each record including sample representations of a plurality of sample 3D object models positioned relative to a sample 2D floor plan, a sample prompt indicating an adaptation of pose of a first set of the sample 3D object models, and a ground truth indicating adaptation of the first set and of a second set of the sample 3D object models which were excluded from the sample prompt and are adapted in response to the prompt.

10. The computer implemented method of claim 1, wherein the GUI is further configured for a user to place a virtual camera at a selected pose within the 2D floor plan overlaid with 3D object models, and further comprising generating an image depicting the 3D object models within a virtual 3D premises corresponding to the 2D floor plan as seen by the virtual camera from the selected pose.

11. The computer implemented method of claim 1, further comprising classifying rooms and/or regions of the 2D floor plan, wherein the 3D object models are positioned within the rooms and/or regions according to the classification and for complying with the target interior design plan.

12. The computer implemented method of claim 1, further comprising: obtaining from the GenAI model in response to the feeding, a proposed structural adaptation of the 2D floor plan for complying with the target interior design plan, wherein the proposed structural adaptation is dynamically adapted in response to the adaptation of the pose of the 3D object models.

13. The computer implemented method of claim 1, further comprising accessing at least one profile of one or more subjects expected to occupy the premises and/or of the premises, and automatically generating the target interior design plan according to the at least one profile.

14. The computer implemented method of claim 13, wherein the at least one profile includes at least one of: expected use of the premises by the subjects, type of premises, geographical location of the premises, number of subjects, hobby of the subjects, seasonal trends, dimensions of the premises, personalized preference of the subjects, maximum estimated costs for implementing the target design plan, and preferred suppliers of features to be implemented according to the target interior design plan, wherein the target interior design plan is automatically generated by feeding the at least one profile into a machine learning model trained on a dataset of records, wherein a record includes at least one sample profile and a ground truth of at least one sample interior design plan corresponding to the at least one sample profile.

15. The computer implemented method of claim 1, wherein the target interior design plan is for a type of accessibility for a disabled individual, wherein the pose of the second set of 3D object models outputted by the GenAI model complies with the type of accessibility.

16. The computer implemented method of claim 15, further comprising simulating the disabled individual with the type of accessibility maneuvering within a 3D model of the premises corresponding to the 2D floor plan for identifying whether the pose of the second set of 3D object models complies with the type of accessibility when the simulation indicates successful maneuvering by the simulated disabled individual, or whether the pose of the second set of 3D object models does not comply with the type of accessibility with the simulation indicates failure to maneuver by the simulated disabled individual and further comprising in response to detecting the failure to maneuver by the simulated disabled individual, automatically instructing the GenAI model for re-generating the pose for obtaining success in the maneuver.

17. The computer implemented method of claim 16, wherein the at least one image comprises a video captured by a camera of a smartphone scanning the interior.

18. The computer implemented method of claim 1, further comprising:
receiving via the GUI, another adaptation of a pose of a third set of 3D object models within the 2D floor plan, wherein 3D object models of the third set are selected from the first set and/or the second set;
feeding into the GenAI model, a prompt comprising the adaptation of the pose of the third set; and
dynamically updating the GUI for presenting an adaptation of a pose of a fourth set of 3D object models outputted by the GenAI model and complying with the target interior design plan,
wherein 3D objects of the fourth set are excluded from the prompt fed into the GenAI model that includes the adaptation of the third set.

19. The computer implemented method of claim 1, further comprising iterating the receiving via the GUI, the feeding into the GenAI, and the dynamically updating the GUI, wherein in each iteration another set of 3D objects is adapted by a user via the GUI, wherein 3D objects of the another set are selected from 3D objects adapted by the user in a preceding iteration and 3D objects automatically adapted by the GenAI model in a preceding iteration.

20. A system for generating a model of a premises with objects therein, comprising:
at least one processor executing a code for:
accessing a 2D floor plan of the premises;
accessing a representation of a plurality of objects complying with a target interior design plan;
feeding a combination of the 2D floor plan and the representation of the plurality of objects into a generative artificial intelligence (GenAI) model;
presenting within a graphical user interface (GUI), a plurality of the objects depicted as 3D object models complying with the target interior design plan outputted by the GenAI model and overlaid on the 2D floor plan;
receiving via the GUI, an adaptation of a pose of a first set of 3D object models within the 2D floor plan;
feeding into the GenAI model, a prompt comprising the adaptation of the pose; and
dynamically updating the GUI for presenting an adaptation of a pose of a second set of 3D object models outputted by the GenAI model and complying with the target interior design plan,
wherein 3D objects of the second set are excluded from the prompt fed into the GenAI model that includes the adaptation of the first set.
